(19) United States
(12) Patent Application Publication
(10) Pub. No.: US 2026/0290746 A1
(43) Pub. Date: Sep. 24, 2026

(54) ELECTRON BEAM IRRADIATION APPARATUS AND CONTACT POINT CONDUCTIVITY INSPECTION METHOD

(71) Applicant: NuFlare Technology, Inc., Yokohama-shi (JP)

(72) Inventor: Yuichi MAEKAWA, Yokohama-shi (JP)

(73) Assignee: NuFlare Technology, Inc., Yokohama-shi (JP)

(21) Appl. No.: 19/556,419

(22) Filed: Mar. 4, 2026

(30) Foreign Application Priority Data
Mar. 21, 2025 (JP) 2025-047092

(51) Int. Cl. H01J 37/24

(52) U.S. Cl. CPC H01J 37/24; H01J 2237/0048

(57) ABSTRACT

According to one aspect of the present invention, an electron beam irradiation apparatus includes an inspection power supply connected to at least one contact point of a plurality of contact points, and configured, in a state in which a retarding potential has been applied to the plurality of contact points, to apply an inspection electric potential to be superimposed on the retarding potential, and a current detector connected to at least one other contact point which is different from the at least one contact point of the plurality of contact points, and configured, in a state in which the retarding potential has been applied to the plurality of contact points, and, further, the inspection electric potential has been applied, superimposed on the retarding potential, to the at least one contact point, to detect a current flowing through the at least one other contact point.

### CROSS-REFERENCE TO RELATED APPLICATION

This application is based upon and claims the benefit of priority from prior Japanese Patent Application No. 2025-047092 filed on Mar. 21, 2025 in Japan, the entire contents of which are incorporated herein by reference.

### BACKGROUND OF THE INVENTION

### Field of the Invention

One aspect of the present invention relates to an electron beam irradiation apparatus and a contact point conductivity inspection method, and, for example, relates to a method for inspecting conductivity of a contact point which applies a retarding potential to a target object irradiated with electron beams.

### Description of Related Art

With recent progress in high integration and large capacity of the Large Scale Integrated circuits (LSI), the line width (critical dimension) necessary for circuits of semiconductor elements is further decreasing. Since LSI manufacturing needs an enormous production cost, it is essential to improve the yield. However, as typified by 1 gigabit DRAMs (Dynamic Random Access Memories), the size of patterns that make up LSIs has been reduced to the order of nanometers from submicrons. Also, in recent years, with miniaturization of dimensions of LSI patterns formed on a semiconductor wafer, dimensions to be detected as a pattern defect have become extremely small. Therefore, the pattern inspection apparatus which inspects, with electron beams, defects of ultrafine patterns on an exposure mask and ultrafine patterns exposed (transferred) to the semiconductor wafer needs to be highly accurate.

The inspection apparatus acquires a pattern image by, for example, irradiating an inspection target substrate with multiple primary electron beams and detecting a secondary electron corresponding to each beam emitted from the inspection target substrate. As an inspection method, there is known a method of comparing a measured image acquired by imaging a pattern formed on a substrate with design data or with another measured image acquired by imaging an identical pattern on the same substrate. For example, as pattern inspection methods, there are a “die-to-die inspection” method and a “die-to-database inspection” method. Specifically, the “die-to-die inspection” method compares data of measured images acquired by imaging identical patterns at different positions on the same substrate. The “die-to-database inspection” method generates design image data (reference image) based on pattern design data, and compares it with a measured image being measured data acquired by imaging a pattern. Acquired images are transmitted as measured data to a comparison circuit. After performing alignment between the images, the comparison circuit compares the measured data with reference data according to an appropriate algorithm, and determines that there is a pattern defect if the compared data do not match each other.

In the electron beam inspection apparatus, a retarding potential is applied to a target object in order to adjust landing energy of electron beams incident on the target object. Accordingly, it becomes necessary to check conduction between the target object and a contact point which applies a retarding potential to the target object.

Conventionally, a method has been used in which a circuit which applies a retarding potential is turned off by switching the circuit to an inspection circuit by a relay etc. and a conduction check is performed between a target object and a contact point by the inspection circuit. However, according to this method, it is difficult to directly check the conductive state between the contact point and the target object during applying a retarding potential. Therefore, it results in indirectly checking, depending on appropriateness of an acquired image, whether a retarding potential has been applied to the target object or not. Consequently, since a change of the conductive state cannot be detected if the change occurs during inspection, it is difficult to determine up to what point the image acquirement was in a normal state. Thus, re-inspection is needed, and therefore, the inspection time is increased. Furthermore, if the conductive state between a contact point and a target object is severely impaired while a retarding potential is being applied, damage to the target object may occur by an electric discharge, etc. Such a problem may happen not only in an inspection apparatus but also in an apparatus which applies a retarding potential to a target object and irradiates electron beams to it.

There is disclosed a method in which, when an observation target object is moved in a target object chamber, an alternating-current voltage is applied, superimposed on a direct-current voltage for a retarding function, to the backside of the observation target object, and a component of the applied alternating-current is taken out via a filter to be monitored in order to detect that the observation target object contacts a structural member such as an inner wall, lens inside the target object chamber (refer to Japanese Patent Application Laid-open (JP-A) No. 2007-324099).

### BRIEF SUMMARY OF THE INVENTION

According to one aspect of the present invention, an electron beam irradiation apparatus includes
a stage configured to mount thereon a target object,
an electron beam column configured to irradiate the target object with an electron beam,
a plurality of contact points connected to the target object and each configured to apply a retarding potential to the target object,
a retarding power supply configured to apply the retarding potential to the plurality of contact points,
an inspection power supply connected to at least one contact point of the plurality of contact points, and configured, in a state in which the retarding potential has been applied to the plurality of contact points, to apply an inspection electric potential to be superimposed on the retarding potential, and
a current detector connected to at least one other contact point which is different from the at least one contact point of the plurality of contact points, and configured, in a state in which the retarding potential has been applied to the plurality of contact points, and, further, the inspection electric potential has been applied, superimposed on the retarding potential, to the at least one contact point, to detect a current flowing through the at least one other contact point.

According to another aspect of the present invention, a contact point conductivity inspection method includes
applying a retarding potential to a target object placed on a stage via each of a plurality of contact points connected to the target object,
applying, in a state in which the retarding potential has been applied to the plurality of contact points, an inspection electric potential, to be superimposed on the retarding potential, to at least one contact point of the plurality of contact points,
detecting, in a state in which the retarding potential has been applied to the plurality of contact points, and, further, the inspection electric potential has been applied, superimposed on the retarding potential, to the at least one contact point, a current flowing through at least one other contact point which is different from the at least one contact point of the plurality of contact points,
calculating, using a detected current value, a resistance, which is through the target object, between the at least one contact point and the at least one other contact point, and
determining, using the resistance, whether a contact between the target object and either one of the at least one contact point and the at least one other contact point of the plurality of contact points has been damaged, and outputting a result of the determining.

### BRIEF DESCRIPTION OF THE DRAWINGS

FIG. 1 is an illustration showing an example of a configuration of a pattern inspection apparatus according to a first embodiment;

FIG. 2 is an illustration showing an example of a configuration of an aperture array substrate according to the first embodiment;

FIG. 3 is a top view showing an example of a substrate cover according to the first embodiment;

FIG. 4 is a sectional view showing an example of a substrate cover according to the first embodiment;

FIG. 5 is a circuit diagram for explaining a method of conductivity inspection according to a comparative example of the first embodiment;

FIG. 6 is a block diagram showing an example of an internal configuration of a contact point conductivity inspection circuit according to the first embodiment;

FIG. 7 is a circuit diagram for explaining a method of conductivity inspection according to the first embodiment;

FIG. 8 is an illustration showing an example of a core of a transformer according to the first embodiment;

FIG. 9 is an illustration for explaining an inductive inspection circuit according to the first embodiment;

FIG. 10 is an illustration showing an example of a voltage waveform and a current waveform according to the first embodiment;

FIG. 11 is an illustration for explaining a method of phase detection according to the first embodiment;

FIG. 12 is a circuit diagram for explaining a method of conductivity inspection according to a modified example of the first embodiment;

FIG. 13 is an illustration for describing an image acquisition processing according to the first embodiment;

FIG. 14 is a diagram showing an example of an internal configuration of a comparison circuit according to the first embodiment;

FIG. 15 is a block diagram showing an example of an internal configuration of a contact point conductivity inspection circuit according to a second embodiment;

FIG. 16 is a circuit diagram for explaining a method of conductivity inspection according to the second embodiment;

FIG. 17 is an illustration for explaining an example of applying an electric potential according to the second embodiment; and

FIG. 18 is a block diagram showing another example of an internal configuration of a contact point conductivity inspection circuit according to the second embodiment.

### DETAILED DESCRIPTION OF THE INVENTION

Embodiments of the present invention provide an apparatus and method that can check a conductive state between a contact point and a target object during applying a retarding potential.

Embodiments of the present invention describes an electron beam inspection apparatus as an example of an electron beam irradiation apparatus or an electron beam image acquisition apparatus. The electron beam irradiation apparatus is not limited to an inspection apparatus, and any apparatus is acceptable as long as it irradiates multiple electron beams on a substrate. Furthermore, a multiple electron beam image acquisition apparatus is not limited to an inspection apparatus, and any apparatus is acceptable as long as it irradiates a substrate with electron beams and acquires an image by detecting a secondary electron emitted from the substrate. The electron beam is not limited to multiple beams, and thus, a configuration using a single beam is also acceptable.

### First Embodiment

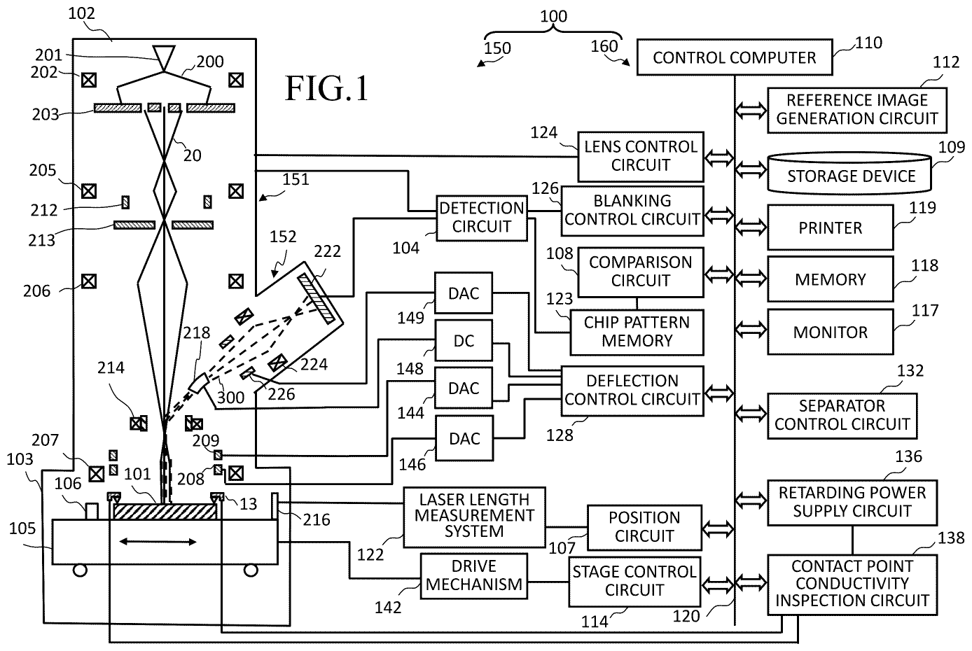

FIG. 1 is an illustration showing an example of a configuration of a pattern inspection apparatus according to a first embodiment. In FIG. 1, an inspection apparatus 100 which inspects patterns formed on the substrate is an example of a multi-electron beam inspection apparatus. The inspection apparatus 100 includes an image acquisition mechanism 150 and a control system circuit 160. The image acquisition mechanism 150 includes an electron beam column (electron optical column), an inspection chamber 103, a detection circuit 104, a chip pattern memory 123, a stage drive mechanism 142, and a laser length measurement system 122. In the electron beam column 102, there are arranged an electron gun 201, an electromagnetic lens 202, an aperture array substrate 203, an electromagnetic lens 205, a collective deflector 212, a limiting aperture substrate 213, an electromagnetic lens 206, a deflector 208, a deflector 209, an electromagnetic lens 207, a beam separator 214 (an example of a separator), a deflector 218, a deflector 226, an electromagnetic lens 224, and a multi-detector 222.

A primary electron optical system 151 is composed of the electron gun 201, the electromagnetic lens 202, the aperture array substrate 203, the electromagnetic lens 205, the collective deflector 212, the limiting aperture substrate 213, the electromagnetic lens 206, the deflector 209, the deflector 208, and the electromagnetic lens 207 (objective lens). A secondary electron optical system 152 is composed of the electromagnetic lens 207 (objective lens), the deflector 208, the deflector 209, the beam separator 214, the deflector 218, the deflector 226, and the electromagnetic lens 224.

The deflectors 209 and 208, and the electromagnetic lens 207 (objective lens) are arranged on the common trajectory of the first and second trajectories. In the example of FIG. 1, the deflectors 209 and 208, and the electromagnetic lens 207 (objective lens) are arranged between the beam separator 214 and the substrate 101.

In the inspection chamber 103, there is disposed a stage 105 movable at least in the x and y directions. On the stage 105, a substrate 101 (target object) to be inspected is placed. The substrate 101 may be an exposure mask substrate, or a semiconductor substrate such as a silicon wafer. In the case of the substrate 101 being a semiconductor substrate, a plurality of chip patterns (wafer die) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed and transferred onto the semiconductor substrate a plurality of times, a plurality of chip patterns (wafer die) are formed on the semiconductor substrate. The case of the substrate 101 being an exposure mask substrate is mainly described below. The substrate 101 is placed, with its pattern-forming surface facing upward, on the stage 105, for example. The substrate 101 is supported at three points by three support members (not shown), for example.

On the substrate 101, a substrate cover 13 is arranged.

On the stage 105, a mirror 216 is arranged which reflects a laser beam, for laser length measuring, emitted from the laser length measuring system 122 placed outside of the inspection chamber 103. Furthermore, on the stage 105, a mark stand 106 is arranged. A mark is formed on the surface of the mark stand 106. As a mark, for example, a cross pattern is used. The height position of the surface of the mark stand 106 is arranged to be flush with the surface of the substrate 101.

The multi-detector 222 is connected, at the outside of the electron beam column 102, to the detection circuit 104. The detection circuit 104 is connected to the chip pattern memory 123.

In the control system circuit 160, a control computer 110 which controls the whole of the inspection apparatus 100 is connected, via a bus 120, to a position circuit 107, a comparison circuit 108, a reference image generation circuit 112, a stage control circuit 114, a lens control circuit 124, a blanking control circuit 126, a deflection control circuit 128, a separator control circuit 132, a retarding power supply circuit 136, a contact point conductivity inspection circuit 138, a storage device 109 such as a magnetic disk drive, a monitor 117, a memory 118, and a printer 119.

The deflection control circuit 128 is connected to DAC (digital-to-analog conversion) amplifiers 144, 146, and 149. The DAC amplifier 146 is connected to the deflector 208, the DAC amplifier 144 is connected to the deflector 209, and the DAC amplifier 149 is connected to the deflector 226. The deflection control circuit 128 is connected to a direct current power supply 148. The direct current power supply 148 is connected to the deflector 218 (vendor).

The chip pattern memory 123 is connected to the comparison circuit 108. The stage 105 is driven by the drive mechanism 142 under the control of the stage control circuit 114. In the drive mechanism 142, for example, a drive system such as a three (x-, y-, and θ-) axis motor driving in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measuring system 122, and supplied (transmitted) to the position circuit 107. Based on the principle of laser interferometry, the laser length measuring system 122 measures the position of the stage 105 by receiving a reflected light from the mirror 216. In the stage coordinate system, the x, y, and θ directions of the primary coordinate system are set, for example, with respect to the plane perpendicular to the optical axis of multiple primary electron beams 20.

The electromagnetic lenses 202, 205, 206, 207, and 224, and the beam separator 214 are controlled by the lens control circuit 124. The collective deflector 212 is composed of two or more electrodes (or poles), and each electrode is controlled by the blanking control circuit 126 via a DAC amplifier (not shown). The deflector 209 is composed of four or more electrodes (or poles), and each electrode is controlled by the deflection control circuit 128 via the DAC amplifier 144. The deflector 208 is composed of four or more electrodes (or poles), and each electrode is controlled by the deflection control circuit 128 via the DAC amplifier 146. The deflector 226 is composed of four or more electrodes (or poles), and each electrode is controlled by the deflection control circuit 128 via the DAC amplifier 149.

The deflector 218 (vendor) is, for example, an arc-shaped bending tube, composed of two or more electrodes (or poles), and each electrode is controlled by the deflection control circuit 128 via the direct current power supply 148. Alternatively, the deflector 218 may be a tablet, composed of two or more electrodes (or poles), and each electrode is controlled by the deflection control circuit 128 via the direct current power supply 148. In order to prevent leakage of the electric field, preferably, the whole of a set of the two or more electrodes is surrounded by GND electrodes except for a plane through which a secondary electron beam passes.

The beam separator 214 is controlled by the separator control circuit 132. As the beam separator 214, it is preferable to use, for example, an E×B separator, or an electromagnetic prism. In the case of FIG. 1, an E×B separator is used as the beam separator 214, for example.

A desired retarding potential is applied to the substrate 101 from the retarding power supply circuit 136 via the contact point conductivity inspection circuit 138. For example, a negative potential is applied to the substrate 101.

To the electron gun 201, there is connected a high voltage power supply circuit (not shown). The high voltage power supply circuit applies an acceleration voltage between a filament (not shown) and an extraction electrode (not shown) in the electron gun 201. In addition to applying the acceleration voltage, a predetermined voltage is applied to the extraction electrode, and the cathode is heated to a predetermined temperature, and thereby, electrons from the cathode are accelerated to be emitted as an electron beam 200.

FIG. 1 shows configuration elements necessary for describing the first embodiment. Other configuration elements generally necessary for the inspection apparatus 100 may also be included therein.

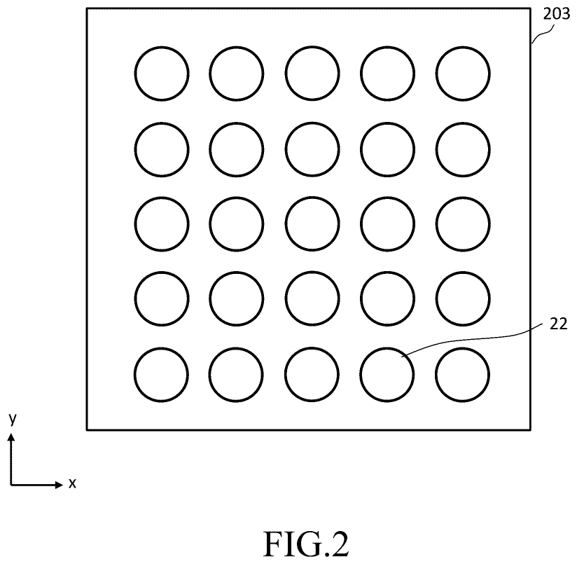

FIG. 2 is an illustration showing an example of a configuration of an aperture array substrate according to the first embodiment. As shown in FIG. 2, holes (openings) 22 of m₁ columns wide (in the x direction) and n₁ rows long (in the y direction), where each of m₁ and n₁ is an integer of 2 or more, are two-dimensionally formed in the x and y directions at the same arrangement pitch in the aperture array substrate 203. In the case of FIG. 2, 5×5 holes 22 (an example of the first openings) are formed. Each of the holes 22 is a circle with the same outer diameter size. The multiple primary electron beams 20 are formed by letting portions of the electron beam 200 individually pass through a corresponding one of a plurality of holes 22. The aperture array substrate 203 serves as an example of a multiple beam forming mechanism which forms multiple primary electron beams.

The image acquisition mechanism 150 acquires an inspection image of a figure pattern formed on the substrate 101 by using multiple electron beams. Hereinafter, operations of the image acquisition mechanism 150 in the inspection apparatus 100 will be explained.

The electron gun 201 (emission source) emits the electron beam 200 in the diverging direction. The electron beam 200 emitted from the electron gun 201 is refracted in the converging direction by the electromagnetic lens 202, and illuminates the whole of a plurality of holes 22 in the aperture array substrate 203. As shown in FIG. 2, a plurality of holes 22 (openings) are formed in the aperture array substrate 203. The region including all of the plurality of holes 22 is irradiated by the electron beam 200. The multiple primary electron beams 20 are formed by letting portions of the electron beam 200 applied to the positions of the plurality of holes 22 individually pass through a corresponding one of the plurality of holes 22 in the aperture array substrate 203.

The formed multiple primary electron beams 20 are individually refracted by the electromagnetic lenses 205 and 206, and travel, while repeating forming an intermediate image and a crossover, to the beam separator 214 located on an intermediate image plane (position conjugate to the image plane) of each beam of the multiple primary electron beams 20. Then, they travel to the electromagnetic lens 207 after passing through the beam separator 214. By disposing the limiting aperture substrate 213 with limited passage holes close to a crossover position of the multiple primary electron beams 20, it becomes possible to block scattered beams. Furthermore, by collectively deflecting all the multiple primary electron beams 20 by the collective deflector 212 and blocking the entire multiple primary electron beams 20 by the limiting aperture substrate 213, it becomes possible to perform blanking of all the multiple primary electron beams 20.

When the multiple primary electron beams 20 enter the electromagnetic lens 207, the multiple primary electron beams 20 are focused to form an image on the substrate 101 by the electromagnetic lens 207. The multiple primary electron beams 20 having been focused on the substrate 101 (target object) by the electromagnetic lens 207 are collectively deflected by the deflectors 208 and 209 to irradiate respective beam irradiation positions on the substrate 101. Thus, this is how the substrate 101 is irradiated with the multiple primary electron beams by the primary electron optical system. Although FIG. 1 shows the case where the multiple primary electron beams 20 are focused to form an image on the substrate 101 by one electromagnetic lens 207, it is not limited thereto. It is also preferable that a plurality of electromagnetic lenses focus the multiple primary electron beams 20 to form an image on the substrate 101.

When desired positions on the substrate 101 are irradiated with the multiple primary electron beams 20, a flux of secondary electrons (multiple secondary electron beams 300), including reflected electrons, each corresponding to each beam of the multiple primary electron beams 20 is emitted from the substrate 101 due to the irradiation with the multiple primary electron beams 20.

The multiple secondary electron beams 300 emitted from the substrate 101 pass through the electromagnetic lens 207 and travel to the beam separator 214.

An E×B separator, being an example of the beam separator 214, includes a plurality of, at least four, magnetic poles each having a coil, and a plurality of, at least four, electrodes (poles). A directional magnetic field is generated by these plurality of magnetic poles. Also, a directional electric field is generated by these plurality of electrodes. Specifically, the E×B separator generates an electric field and a magnetic field to be orthogonal to each other in a plane perpendicular to the traveling direction of the center beam (i.e., trajectory central axis) of the multiple primary electron beams 20. The electric field exerts a force in a fixed direction regardless of traveling direction of electrons. In contrast, the magnetic field exerts a force according to Fleming's left-hand rule. Therefore, the direction of the force acting on (applied to) electrons can be changed depending on the entering (or “traveling”) direction of electrons. With respect to the multiple primary electron beams 20 entering the E×B separator from above, since the forces due to the electric field and the magnetic field cancel each other out, the multiple primary electron beams 20 travel straight downward. In contrast, with respect to the multiple secondary electron beams 300 entering the E×B separator from below, since both the forces due to the electric field and the magnetic field are exerted in the same direction, the multiple secondary electron beams 300 are statically bent obliquely upward, and separated from the trajectory of the multiple primary electron beams 20.

The multiple secondary electron beams 300 having been bent obliquely upward and separated from the multiple primary electron beams 20 are led to the multi-detector 222 by the secondary electron optical system 152. Specifically, the multiple secondary electron beams 300 separated from the multiple primary electron beams 20 travel to the deflector 218. The deflector 218 is disposed on the trajectory of the multiple secondary electron beams 300 separated from the trajectory of the multiple primary electron beams 20, and at the position conjugate to the detection surface of the multi-detector 222. Specifically, the deflector 218 is arranged such that a mid-way position (e.g., intermediate position) in the deflector 218 is conjugate to the detection surface of the multi-detector 222. The multiple secondary electron beams 300 are further bent by being statically deflected by the deflector 218. Then, the multiple secondary electron beams 300 statically deflected by the deflector 218 are projected on the multi-detector 222 while being refracted in a converging direction by the electromagnetic lens 224, at the position away from the trajectory of the multiple primary electron beams 20. The multi-detector 222 (multiple secondary electron beam detector) individually detects the multiple secondary electron beams 300 having been refracted and projected.

The multi-detector 222 includes a plurality of detection elements (e.g., diode type two-dimensional sensor. At the detection surface of the multi-detector 222, each beam of the multiple secondary electron beams 300 collides with a detection element 60 corresponding to each beam of the multiple secondary electron beams 300 and generates electrons. Then, secondary electron image data is generated for each pixel. An intensity signal detected by the multi-detector 222 is output to the detection circuit 104. Thereby, secondary electron images are acquired based on detected signals of the multiple secondary electron beams 300.

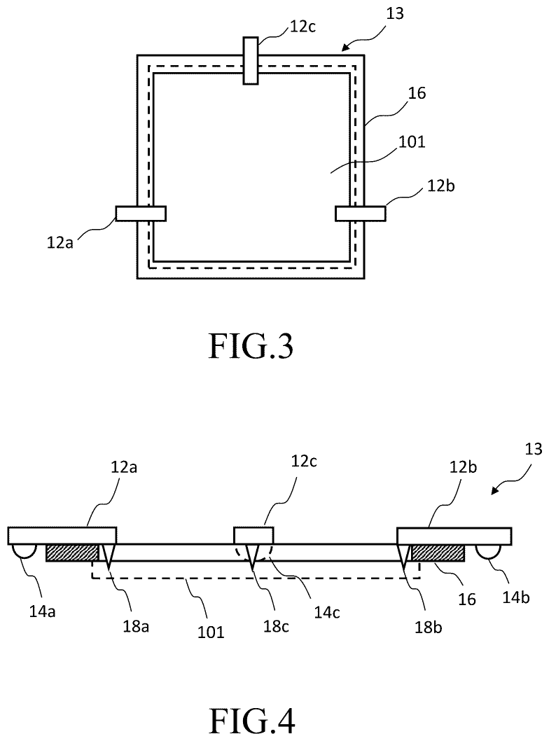

FIG. 3 is a top view showing an example of a substrate cover according to the first embodiment.

FIG. 4 is a sectional view showing an example of a substrate cover according to the first embodiment.

The substrate cover 13 includes three contact support members 12 and a frame 16 (an example of a frame-like member). The contact support members 12 are fixed to the positions supporting the substrate cover 13 by three-point support, from the upper side of the frame 16. The contact support members 12 are fixed such that their ends protrude more inward than the inner peripheral end of the frame 16 and protrude more outward than the outer peripheral end of the frame 16. The contact support members 12 are fixed to the frame 16 by screw clamping or welding, for example. At the backside of each contact support member 12, a pin 18 serving as a contact member is arranged, with its apex facing the backside, at the position more inward than the inner peripheral end of the frame 16. Furthermore, at the backside side of each contact support member 12, a hemispherical convex portion 14 is arranged such that its spherical surface faces the outside at the position more outward than the outer peripheral end of the frame 16.

The frame 16 is configured by a plate, and formed such that its peripheral dimension is larger than the outer peripheral end of the substrate 101, and the dimension of the opening at its central part of the inner side is smaller than the outer peripheral end of the substrate 101. That is, as shown in FIG. 4, the frame 16 is configured such that, when the substrate cover 13 is placed from above to cover the upper part of the substrate 101, the whole periphery of the outer peripheral part of the substrate 101 shown in a dotted line overlaps with the frame 16. Thus, the substrate cover 13 covers the whole periphery of the substrate 101 from above. When the substrate cover 13 is attached to the substrate 101, the three pins 18 cut into the film formed on the substrate 101 to be electrically conducted to the substrate 101. Due to electrically connecting the retarding power supply circuit 136 and each convex portion 14, a retarding potential is applied to each pin 18. Then, a retarding potential is applied to the substrate 101 from each pin 18.

In the inspection apparatus 100, in order to adjust a landing energy of the electron beam entering the substrate 101, a retarding potential is applied to the substrate 101 as described above. Therefore, it is necessary to check conductivity between the substrate 101 and a plurality of pins 18a, 18b, and 18c serving as contact points.

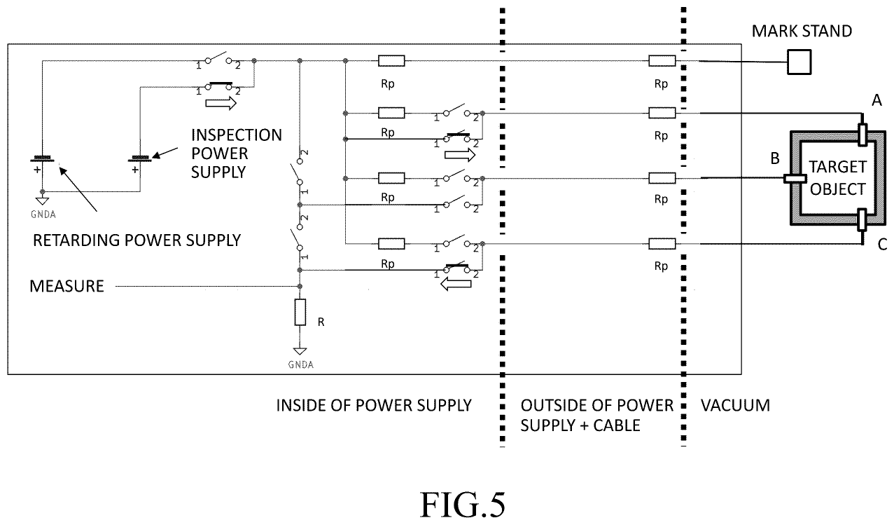

FIG. 5 is a circuit diagram for explaining a method of conductivity inspection according to a comparative example of the first embodiment. In FIG. 5, Rp indicates a resistance. 1 and 2 indicate relay circuits. According to the comparative example, a circuit between a target object and a retarding power supply is interrupted by switching, by a relay, etc., a circuit for applying a retarding potential to a circuit for inspection. Then, instead, the target object and the circuit for inspection are connected. In FIG. 5, a negative potential from the inspection power supply is applied to, for example, to the contact point A of the substrate cover arranged on the target object. Then, a current passing through the target object and flowing to the circuit connected via the contact point C is detected. Similarly, a negative potential is applied to the contact point A, and a current passing through the target object and flowing to the circuit connected via the contact point B is detected. Similarly, a negative potential is applied to the contact point B, and a current passing through the target object and flowing to the circuit connected via the contact point C is detected. The resistance of each circuit is obtained based on a detected current and an electric potential difference between the contact points. The obtained resistance value shows a conductive state between the contact point and the target object.

However, according to this method, it is difficult to directly check a conductive state between the contact point and the target object during applying a retarding potential. Therefore, it results in indirectly checking whether a retarding potential has been applied to the target object or not, depending on appropriateness of an acquired image. Consequently, since a change of the conductive state cannot be detected if the change occurs during inspection, it is difficult to determine up to what point the image acquirement was in a normal state. Thus, re-inspection is needed, and therefore, the inspection time is increased. Furthermore, if the conductive state between a contact point and a target object is severely impaired while a retarding potential is being applied, damage to the target object may occur by an electric discharge, etc. Such a problem may happen not only in an inspection apparatus but also in an apparatus which applies a retarding potential to a target object and irradiates electron beams to it. Then, according to the first embodiment, while a retarding potential is being applied, the conductive state between a contact point and a target object is inspected. The following provides a detailed description.

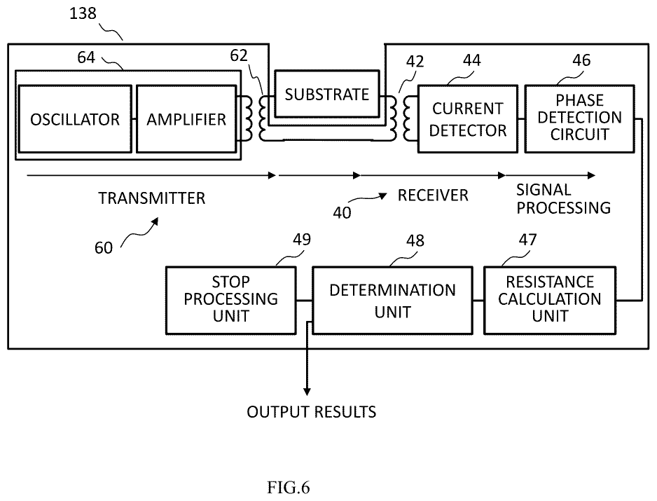

FIG. 6 is a block diagram showing an example of an internal configuration of a contact point conductivity inspection circuit according to the first embodiment. In FIG. 6, in the contact point conductivity inspection circuit 138, there are arranged a transmitter 60, a receiver 40, a phase detection circuit 46, a resistance calculation unit 47, a determination unit 48, and a stop processing unit 49. The transmitter 60 includes a transformer 62 and an inspection power supply (power supply for inspection) 64. The receiver 40 includes a transformer 42 and a current detector 44. Each of the “ . . . units” such as the resistance calculation unit 47, the determination unit 48, and the stop processing unit 49 includes processing circuitry. The processing circuitry includes, for example, an electric circuit, computer, processor, circuit board, quantum circuit, semiconductor device, or the like. Each “ . . . unit” may use common processing circuitry (the same processing circuitry), or different processing circuitry (separate processing circuitry). Input data needed in the resistance calculation unit 47, the determination unit 48, and the stop processing unit 49, or a calculated result is stored in a memory (not shown) or in the memory 118 each time.

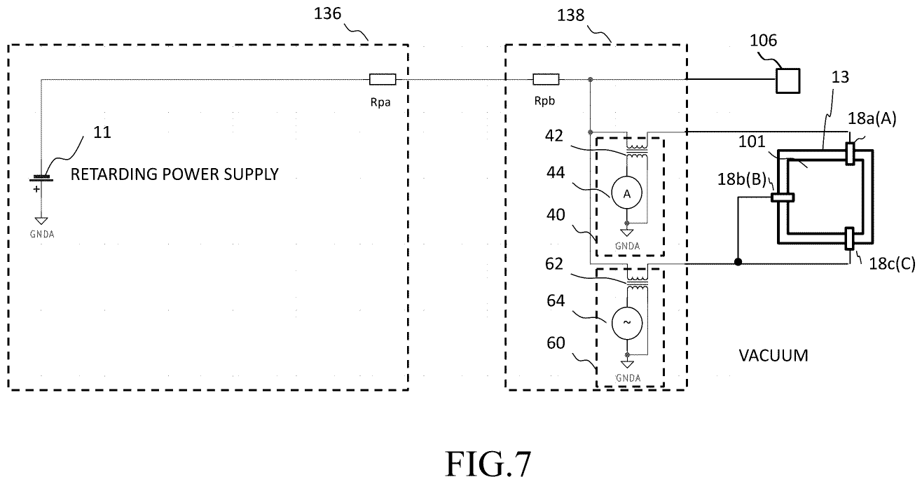

FIG. 7 is a circuit diagram for explaining a method of conductivity inspection according to the first embodiment. In FIG. 7, a resistance Rpa is disposed close to the outlet of the wiring of the retarding power supply circuit 136, and a resistance Rpb is disposed close to the inlet of the wiring of the contact point conductivity inspection circuit 138. In FIG. 7, the phase detection circuit 46, the resistance calculation unit 47, the determination unit 48, and the stop processing unit 49 are not illustrated in the contact point conductivity inspection circuit 138.

In the retarding power supply circuit 136, the retarding power supply 11 and the resistance Rpa are arranged. The negative electrode of the retarding power supply 11 used as a direct current power supply is connected to the contact point conductivity inspection circuit 138 through the resistance Rpa. The positive electrode of the retarding power supply 11 is connected to a ground (GND).

In the contact point conductivity inspection circuit 138, the wiring to which a negative retarding potential is applied branches through the resistance Rpb.

For example, it branches to three lines (or “systems”). The wiring of the first system is connected in parallel, through the transmitter 60, to two contact points B and C (pins 18b and 18c) of the substrate cover 13, for example. The wiring of the second system is connected, through the receiver 40, to one contact point A (pin 18a) of the substrate cover 13, for example. The wiring of the third system is connected to the mark stand 106. The retarding power supply circuit 136 applies a retarding potential to the substrate 101 through a plurality of contact points A, B, and C which are connected to the substrate 101 placed on the stage 105. Here, the retarding power supply circuit 136 applies a negative retarding potential to the plurality of contact points A, B, and C. Then, each of the plurality of contact points A, B, and C connected to the substrate 101 applies a retarding potential to the substrate 101. By this, the same retarding potential is applied to both the substrate 101 and the mark stand 106, and therefore, they become equipotential.

In FIG. 7, the inspection power supply 64 is non-contact electrically connected to a circuit which applies a retarding potential to at least one contact point (e.g., the contact point B or C) of a plurality of contact points A, B, and C. Specifically, the primary side coil and the secondary side coil of the transformer 62 (first transformer) are arranged in non-contact. The inspection power supply 64 is connected to the primary side coil of the transformer 62. For example, the circuit which applies a retarding potential to the contact points B and C is connected to the secondary side coil of the transformer 62. In the case of FIG. 7, the inspection power supply 64 side is illustrated as the primary side, and the substrate 101 side is as the secondary side. The following provides a detailed description.

The wiring of the first system branched close to the inlet of the contact point conductivity inspection circuit 138 is connected to one terminal of the secondary side coil of the transformer 62 of the transmitter 60. The other terminal of the secondary side coil of the transformer 62 is connected in parallel, for example, to the two contact points B and C (pins 18b and 18c) of the substrate cover 13. One terminal of the primary side coil of the transformer 62 is connected to one terminal of the inspection power supply 64. Both of the other terminal of the primary side coil of the transformer 62 and the other terminal of the inspection power supply 64 are connected to a ground (GND). The ratio between the number of turns of the primary side coil of the transformer 62 and that of the secondary side coil is N1:1.

In FIG. 7, the current detector 44 is non-contact electrically connected to a circuit which applies a retarding potential to at least one other contact point (e.g., the contact point A) which is different from the above-described at least one contact point (e.g., the contact point B or C) of a plurality of contact points A, B, and C. Specifically, the primary side coil and the secondary side coil of the transformer 42 (second transformer) are arranged in non-contact. The current detector 44 is connected to the secondary side coil of the transformer 42. For example, the circuit which applies a retarding potential to the contact point A is connected to the primary side coil of the transformer 42. In the case of FIG. 7, the substrate 101 side is illustrated as the primary side, and the current detector 44 side is as the secondary side. The following provides a detailed description.

The wiring of the second system branched close to the inlet of the contact point conductivity inspection circuit 138 is connected to one terminal of the primary side coil of the transformer 42 of the receiver 40. The other terminal of the primary side coil of the transformer 42 is connected, for example, to one contact point A (pin 18a) of the substrate cover 13. One terminal of the secondary side coil of the transformer 42 is connected to one terminal of the current detector 44. Both of the other terminal of the secondary side coil of the transformer 42 and the other terminal of the current detector 44 are connected to a ground (GND). The ratio between the number of turns of the primary side coil of the transformer 42 and that of the secondary side coil is 1:N2

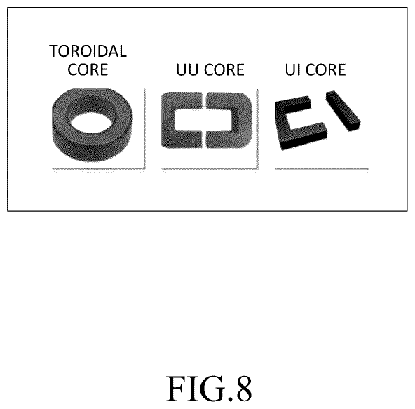

FIG. 8 is an illustration showing an example of a core of a transformer according to the first embodiment. As a core of the transformers 62 and 42 of the first embodiment, a core which can be arranged in toroid is used. As shown in FIG. 8, preferably, a toroidal core, a UU core, or a UI core is used, for example.

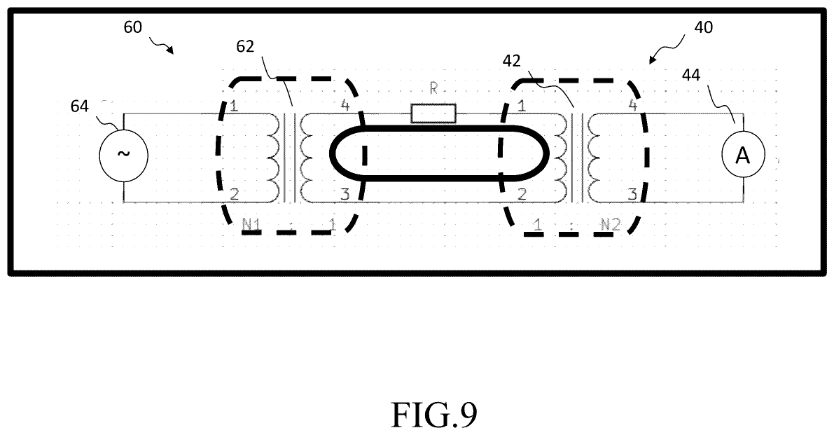

FIG. 9 is an illustration for explaining an inductive inspection circuit according to the first embodiment. In the first embodiment, a closed circuit is formed through at least one contact point (e.g., the contact point B or C), the substrate 101, and at least one other contact point (e.g., the contact point A). Then, an inductive inspection circuit which applies an inspection electric potential Vin to the closed circuit through the transformer 62, and detects a current I through the transformer 42 is formed. In the inductive inspection circuit, the resistance R through at least one contact point (e.g., the contact point B or C), the substrate 101, and at least one other contact point (e.g., the contact point A) can be defined by the following equation (1).

$$R = ( Vin / N 1 ) / ( I / N 2 ) \qquad ( 1 )$$

Then, in the state in which a retarding potential has been applied to a plurality of contact points A, B, and C (pins 18a, 18b, and 18c), the inspection power supply 64 applies the inspection electric potential Vin, superimposed on the retarding potential, to at least one contact point of the plurality of contact points A, B, and C. An alternating current potential is used for the inspection electric potential Vin. For example, the inspection electric potential Vin which has been oscillated at a frequency of 1 to 5 kHz (e.g., 2 kHz), for example, by the oscillator, and amplified to 1 to 5 V (e.g., 2 V), for example, is output. For example, the inspection electric potential Vin, which is a sufficiently small alternating current with respect to a retarding potential having a strong electric potential such as −15 kV, is output.

Then, in the state in which a retarding potential has been applied to a plurality of contact points A, B, and C (pins 18a, 18b, and 18c), and, further, the inspection electric potential Vin has been applied, to be superimposed on the retarding potential, to at least one contact point (e.g., the contact point B or C) of the plurality of contact points A, B, and C, the current detector 44 detects the current I flowing through at least one other contact point (e.g., the contact point A) of the plurality of contact points A, B, and C.

Therefore, by detecting the current I, the resistance R through at least one contact point (e.g., the contact point B or C), the substrate 101, and at least one other contact point (e.g., the contact point A) can be calculated.

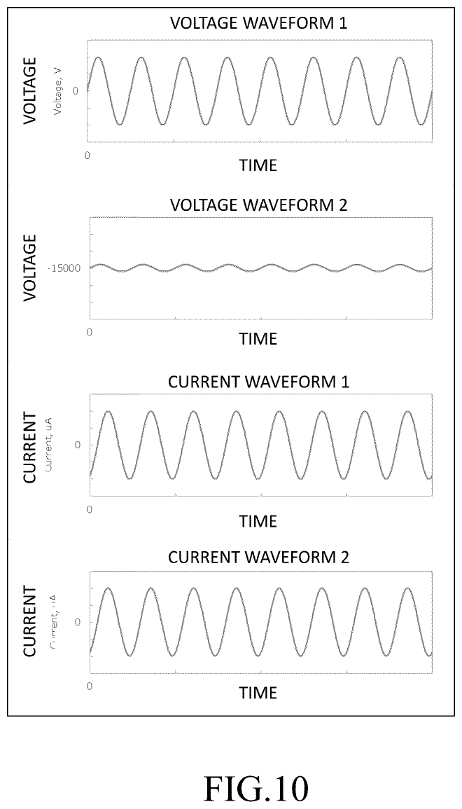

FIG. 10 is an illustration showing an example of a voltage waveform and a current waveform according to the first embodiment. In FIG. 10, the voltage waveform 1 shows an example of an alternating voltage waveform at the primary side of the transmitter 60. The ordinate axis of the voltage waveform 1 represents a voltage, and the abscissa axis represents a time. The voltage waveform 1 shows the case where the frequency is 2 kHz, and the amplitude is 2 V, for example. The voltage waveform 2 shows an example of an alternating voltage waveform at the secondary side of the transmitter 60. The ordinate axis of the voltage waveform 2 represents a voltage, and the abscissa axis represents a time. The voltage waveform 2 shows the case where, for example, an inspection voltage (an electric potential difference between the inspection electric potential Vin and a ground potential), whose frequency is 2 kHz and amplitude is 2 V, is superimposed on a retarding voltage (an electric potential difference between a retarding potential and a ground potential) of −15 kV, for example. The current waveform 1 shows an example of an alternating current waveform at the primary side of the receiver 40. The ordinate axis of the alternating current waveform 1 represents a current and the abscissa axis shows a time. The current waveform 2 shows an example of an alternating current waveform at the secondary side of the receiver 40. The ordinate axis of the alternating current waveform 2 represents a current, and the abscissa axis represents a time. The amplitude of the alternating current waveform 2 indicates 1/N2 of the amplitude of the alternating current waveform 1.

The current detector 44 detects a current waveform 2.

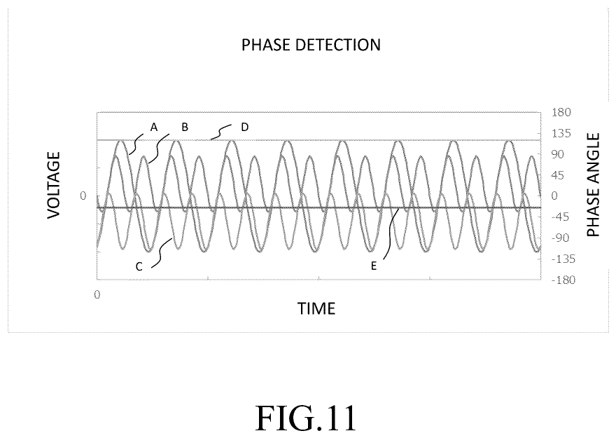

FIG. 11 is an illustration for explaining a method of phase detection according to the first embodiment. In FIG. 11, the ordinate axis represents a voltage and a phase angle, and the abscissa axis represents a time. In the case of FIG. 11, the graph A shows a current waveform 2 detected by the current detector 44. For example, when the transmitter 60 is operated at the frequency 2 kHz, the phase detection frequency is set to be 2 kHz in order to extract a 2 kHz component. The phase detection circuit 46, first, calculates a sine wave of the current waveform 2 with an amplitude (2 kHz), as sine detection (graph B). The phase detection circuit 46 calculates a cosine wave of the current waveform 2 with an amplitude (2 kHz), as cosine detection (graph C). The phase detection circuit 46 calculates a square root (average ((sine detection)²+(cosine detection)²))×√2, as the current I (graph D). The phase (graph E) can be calculated by Arctan (average(sine detection)/average(cosine detection)).

Using a detected current value I, the resistance calculation unit 47 calculates a resistance R, which is through the substrate 101, between at least one contact point (e.g., the contact point B or C) and at least one other contact point (e.g., the contact point A). Specifically, the resistance calculation unit 47 calculates a resistance R through at least one contact point (e.g., the contact point B or C), the substrate 101, and at least one other contact point (e.g., the contact point A) by substituting the inspection electric potential Vin, a measured current I, and ratios of the number of turns N1 and N2 into the equation (1).

Using the resistance R, the determination unit 48 determines whether a contact between the substrate 101 and either at least one contact point (e.g., the contact point B or C) or at least one other contact point (e.g., the contact point A) of a plurality of contact points A, B, and C has been damaged or not. In other words, it is determined whether a contact defect has been generated between the substrate 101 and either at least one contact point (e.g., the contact point B or C) or at least one other contact point (e.g., the contact point A) of a plurality of contact points A, B, and C. For example, it is determined whether the resistance R is less than or equal to a threshold Th1. If the resistance R is not less than or equal to the threshold Th1, it is determined that the contact has been damaged. The determined result is output to the storage device 118 and the like to be stored.

As a result of the determination, if it is determined that a contact between the substrate 101 and either at least one contact point (e.g., the contact point B or C) or at least one other contact point (e.g., the contact point A) of a plurality of contact points A, B, and C has been damaged, the stop processing unit 49 controls the retarding power supply circuit 136 to stop applying a retarding potential. The retarding power supply circuit 136 turns off the retarding power supply 11 to stop applying a retarding potential.

In the examples described above, although it can be known that a contact defect was generated in at least one of the contact points A, B, and C, determining which contact is defective is difficult. Then, it is also preferable to individually measure a resistance between contact points. The following provides a detailed description.

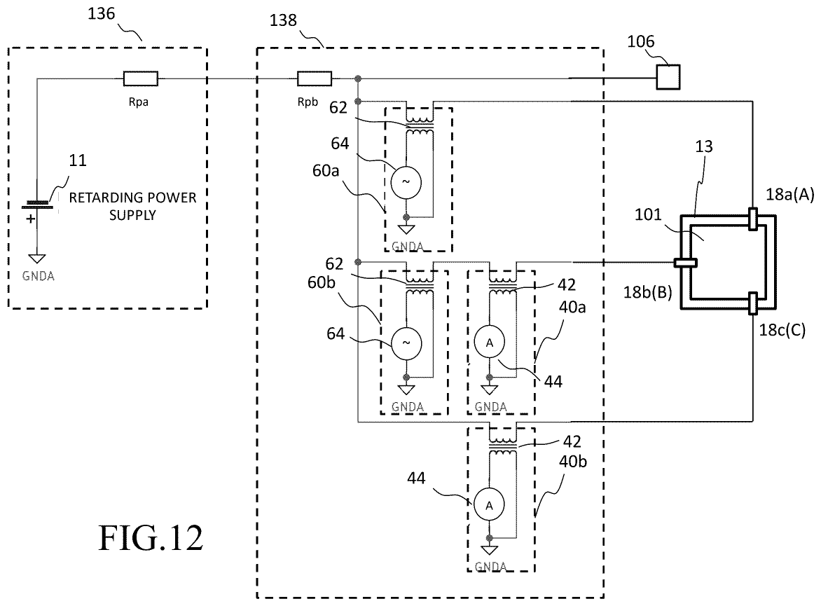

FIG. 12 is a circuit diagram for explaining a method of conductivity inspection according to a modified example of the first embodiment. In FIG. 12, a resistance Rpa is disposed close to the outlet of the wiring of the retarding power supply circuit 136, and a resistance Rpb is disposed close to the inlet of the wiring of the contact point conductivity inspection circuit 138. In the contact point conductivity inspection circuit 138 according to the modified example of the first embodiment, two transmitters 60a and 60b, and two transmitters 40a and 40b are arranged. In FIG. 12, the resistance calculation unit 47, the determination unit 48, and the stop processing unit 49 in the contact point conductivity inspection circuit 138 are not illustrated. In each of the transmitters 60a and 60b, the transformer 62 and the inspection power supply 64 are disposed. In each of the receivers 40a and 40b, the transformer 42 and the current detector 44 are disposed.

In the retarding power supply circuit 136, the retarding power supply 11 and the resistance Rpa are arranged. The negative electrode of the retarding power supply 11 used as a direct current power supply is connected to the contact point conductivity inspection circuit 138 through the resistance Rpa. The positive electrode of the retarding power supply 11 is connected to a ground (GND).

In the contact point conductivity inspection circuit 138, the wiring to which a negative retarding potential is applied branches through the resistance Rpb. For example, it branches to four lines. The wiring of the first system is connected, through the transmitter 60a, to the contact point A (pin 18a) of the substrate cover 13, for example. The wiring of the second system is connected, through the transmitter 60a and the receiver 40a which are connected in series, to one contact point B (pin 18b) of the substrate cover 13, for example. The wiring of the third system is connected, through the receiver 40b, to one contact point C (pin 18c) of the substrate cover 13, for example. The wiring of the fourth system is connected to the mark stand 106. The retarding power supply circuit 136 applies a negative retarding potential to a plurality of contact points A, B, and C. Then, each of the plurality of contact points A, B, and C connected to the substrate 101 applies a retarding potential to the substrate 101. By this, the same retarding potential is applied to both the substrate 101 and the mark stand 106, and therefore, they become equipotential.

In FIG. 12, the inspection power supply 64 of the transmitter 60a is non-contact electrically connected to a circuit which applies a retarding potential to the contact point A. The inspection power supply 64 of the transmitter 60b is non-contact electrically connected to a circuit which applies a retarding potential to the contact point B. The current detector 44 of the receiver 40a is non-contact electrically connected to a circuit which applies a retarding potential to the contact point B. The current detector 44 of the receiver 40b is non-contact electrically connected to a circuit which applies a retarding potential to the contact point C. The ratio between the number of turns of the primary side coil of each transformer 62 of the transmitters 60a and 60b and the number of turns of the secondary side coil is N1:1. The ratio between the number of turns of the primary side coil of each transformer 42 of the receivers 40a and 40b and the number of turns of the secondary side coil is 1: N2.

First, in the state in which the inspection power supply 64 of the transmitter 60b is OFF and a retarding potential has been applied to a plurality of contact points A, B, and C (pins 18a, 18b, and 18c), the inspection power supply 64 of the transmitter 60a applies the inspection electric potential Vin, superimposed on the retarding potential, to the contact point A.

Then, in the state in which a retarding potential has been applied to a plurality of contact points A, B, and C (pins 18a, 18b, and 18c), and, further, the inspection electric potential Vin has been applied, superimposed on the retarding potential, to the contact point A, the current detector 44 of the receiver 40a detects a current Iab flowing through the contact point B. Furthermore, in the state in which a retarding potential has been applied to a plurality of contact points A, B, and C (pins 18a, 18b, and 18c), and, further, the inspection electric potential Vin has been applied, superimposed on the retarding potential, to the contact point A, the current detector 44 of the receiver 40b detects a current Iac flowing through the contact point C.

Next, in the state in which the inspection power supply 64 of the transmitter 60a is OFF and a retarding potential has been applied to a plurality of contact points A, B, and C (pins 18a, 18b, and 18c), the inspection power supply 64 of the transmitter 60b applies the inspection electric potential Vin, superimposed on the retarding potential, to the contact point B.

Then, in the state in which a retarding potential has been applied to a plurality of contact points A, B, and C (pins 18a, 18b, and 18c), and, further, the inspection electric potential Vin has been applied, superimposed on the retarding potential, to the contact point B, the current detector 44 of the receiver 40b detects a current Ibc flowing through the contact point C.

Thus, the current Iab flowing through the contact point A, the substrate 101, and the contact points B, the current Iac flowing through the contact point A, the substrate 101, and the contact point C, and the current Ibc flowing through the contact point B, the substrate 101, and the contact point C can be individually detected. Therefore, the resistance Rab through the contact point A, the substrate 101, and the contact point B, the resistance Rac through the contact point A, the substrate 101, and the contact point C, and the resistance Rbc through the contact point B, the substrate 101, and the contact point C can be individually calculated. By individually obtaining the resistance, the portion of a defect contact point can be narrowed down.

If any one of the resistance Rab through the contact point A, the substrate 101, and the contact point B, the resistance Rac through the contact point A, the substrate 101, and the contact point C and the resistance Rbc through the contact point B, the substrate 101, and the contact point C is not less than or equal to a threshold Th1, the stop processing unit 49 controls the retarding power supply circuit 136 to stop applying a retarding potential.

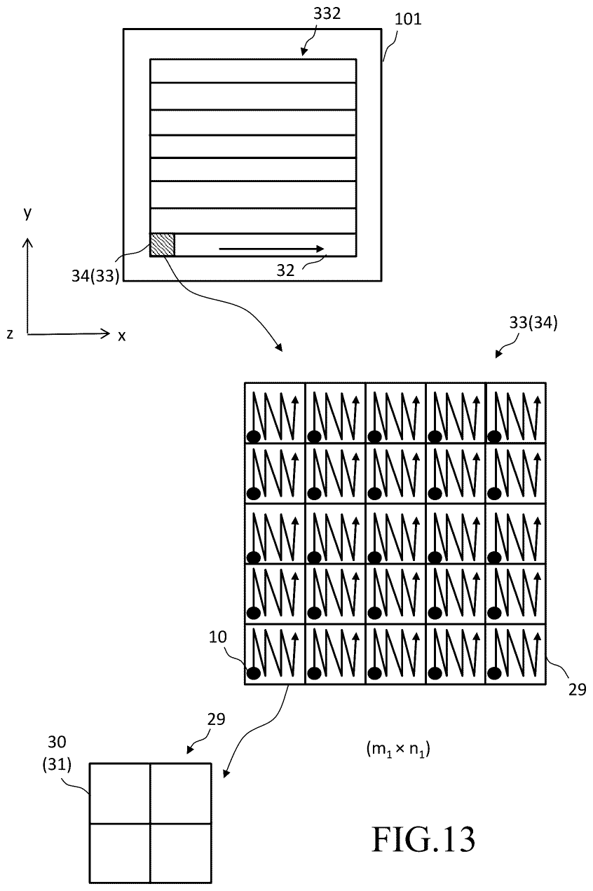

FIG. 13 is an illustration for describing an image acquisition processing according to the first embodiment. As shown in FIG. 13, an inspection region 330 of the substrate 101 is divided, for example, in the y direction into a plurality of stripe regions 32 by a predetermined width. The scanning operation by the image acquisition mechanism 150 is carried out for each stripe region 32, for example. The scanning operation over the stripe region 32 advances relatively in the x direction while the stage 105 is moved in the −x direction, for example. Each stripe region 32 is divided in the longer direction into a plurality of rectangular (including square) regions 33. Beam application to a target rectangular region 33 is achieved by collectively deflecting all the multiple primary electron beams 20 by the deflectors 208 and 209.

FIG. 13 shows the case of the multiple primary electron beams 20 of 5 rows by 5 columns, for example. The size of an irradiation region 34 that can be irradiated with one irradiation of the multiple primary electron beams 20 is defined by (the x-direction size obtained by multiplying the x-direction beam pitch of the multiple primary electron beams 20 on the substrate 101 by the number of x-direction beams)×(the y-direction size obtained by multiplying the y-direction beam pitch of the multiple primary electron beams 20 on the substrate 101 by the number of y-direction beams). The irradiation region 34 serves as a field of view of the multiple primary electron beams 20. A sub-irradiation region 29, in which the beam concerned itself is located and which is surrounded by the beam's x-direction beam pitch and y-direction beam pitch, is irradiated and scanned (scanning operation) with each primary electron beam 10 of the multiple primary electron beams 20. Each primary electron beam 10 is associated with any one of the sub-irradiation regions 29 which are different from each other. Each primary electron beam 10 is applied to the same position in the associated sub-irradiation region 29. The surface of the substrate 101 where a pattern has been formed is scanned by collectively deflecting the multiple primary electron beams 20 by the deflectors 208 and 209. In other words, the primary electron beam 10 is moved in the sub-irradiation region 29 by collective deflection of all of the multiple primary electron beams 20 by the deflectors 208 and 209. By repeating this operation, one sub-irradiation region 29 is irradiated in order with one primary electron beam 10, for example.

Preferably, the width of each stripe region 32 is set to be the same as the y-direction size of the irradiation region 34, or to be the size reduced by the width of the scanning margin. In the case of FIG. 13, the irradiation region 34 and the rectangular region 33 are of the same size. However, it is not limited thereto. The irradiation region 34 may be smaller than the rectangular region 33, or larger than it. Using each primary electron beam 10 of the multiple primary electron beams 20, the sub-irradiation region 29 in which the primary electron beam 10 concerned itself is located is irradiated and scanned (scanning operation) by the primary electron beam 10 concerned. Then, when scanning of one sub-irradiation region 29 is completed, the irradiation position is moved to an adjacent rectangular region 33 in the same stripe region 32 by collective deflection of all the multiple primary electron beams 20 by the deflectors 208 and 209. By repeating this operation, the inside of the stripe region 32 is irradiated in order. After completing scanning of one stripe region 32, the irradiation region 34 is moved to the next stripe region 32 by movement of the stage 105 and/or by collective deflection of all of the multiple primary electron beams 20 by the deflectors 208 and 209. As described above, by irradiation with each primary electron beam 10, the scanning operation per sub-irradiation region 29 and acquisition of a secondary electron image are performed. By combining these secondary electron images of respective sub-irradiation regions 29, a secondary electron image of the rectangular region 33, a secondary electron image of the stripe region 32, or a secondary electron image of a chip 332 is configured. When an image comparison is actually performed, the sub-irradiation region 29 in each rectangular region 33 is further divided into a plurality of frame regions 30, and then, a comparison is performed with respect to a frame image 31 being a measurement image of each frame region 30. FIG. 13 shows the case of dividing the sub-irradiation region 29, which is scanned with one primary electron beam 10, into four frame regions 30 by halving it in the x and y directions, for example.

In the case of applying the multiple primary electron beams 20 to the substrate 101 while the stage 105 is continuously moving, the deflectors 208 and 209 execute a tracking operation by performing collective deflection so that the irradiation position of the multiple primary electron beams 20 may follow the movement of the stage 105.

Thus, in the state in which a retarding potential has been applied to a plurality of contact points A, B, and C, the image acquisition mechanism 150 scans over the substrate 101 with the multiple primary electron beams 20, with respect to each stripe region 32. As described above, the multiple secondary electron beams 300, which are emitted from the substrate 101 due to irradiation with the multiple primary electron beams 20, form an intermediate image plane in the deflector 218, and are deflected statically in the-z direction by the deflector 218 and detected by the multi-detector 222. A reflected electron may be included in detected multiple secondary electron beams 300. Alternatively, a reflected electron may be diverged during moving in the secondary electron optical system not to reach the multi-detector 222. Then, a secondary electron image is acquired based on a signal of detected multiple secondary electron beams 300. Specifically, detection data (measured image data: secondary electron image data: inspection image data) on a secondary electron of each pixel in each sub-irradiation region 29, detected by the multi-detector 222, is output to the detection circuit 104 in the order of measurement. In the detection circuit 104, the detection data in analog form is converted into digital data by an A-D converter (not shown), and stored in the chip pattern memory 123. Then, acquired measured image data is transmitted to the comparison circuit 108, together with information on each position from the position circuit 107.

The reference image generation circuit 112 generates, for each frame region 30, a reference image corresponding to the frame image 31, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data in binary or multiple values.

As described above, basic figures defined by the design pattern data are, for example, rectangles (including squares) and triangles. For example, there is stored figure data which defines the shape, size, position, and the like of each pattern figure by using information, such as coordinates (x, y) of the reference position of the figure, lengths of sides of the figure, and a figure code serving as an identifier for identifying the figure type such as rectangles and triangles.

When design pattern data serving as the figure data is input to the reference image generation circuit 112, the data is developed into data for each figure, and then, the figure code, the figure dimensions, and others indicating the figure shape in each figure data are interpreted. Then, the reference image generation circuit 112 develops each figure data to design pattern image data in binary or multiple values as a pattern to be arranged in squares in units of grids of predetermined quantization dimensions, and outputs the developed data. Expressed in another way, the reference image generation circuit 112 reads design data, calculates the occupancy rate of a figure in the design pattern, for each square region obtained by virtually dividing the inspection region into squares in units of predetermined dimensions, and outputs n-bit occupancy rate data. For example, it is preferable to set one square as one pixel. Assuming that one pixel has a resolution of ½⁸(= 1/256), the occupancy rate in each pixel is calculated by allocating sub-regions, each having 1/256 resolution, which correspond to the region of a figure arranged in the pixel. Then, it is generated as 8-bit occupancy data. Such square regions (inspection pixels) can be corresponding to (commensurate with) pixels of measured data.

Next, the reference image generation circuit 112 performs filtering processing on design image data of a design pattern which is image data of a figure, using a predetermined filter function. Thereby, it becomes possible to match/fit the design image data being design side image data, whose image intensity (gray scale level) is represented by digital values, with image generation characteristics obtained by irradiation with the multiple primary electron beams 20. Image data for each pixel of a generated reference image is output to the comparison circuit 108.

As a comparison step, the comparison circuit 108 compares an inspection image and a reference image. Specifically, it operates as follows.

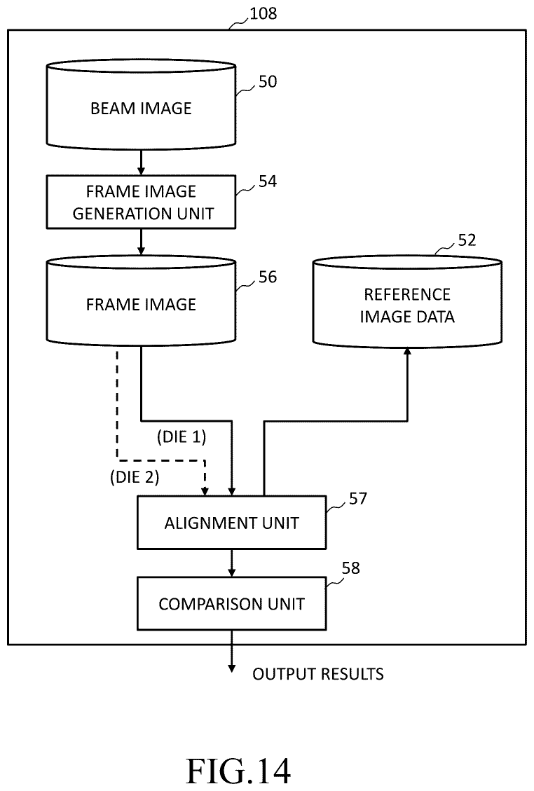

FIG. 14 is a diagram showing an example of an internal configuration of a comparison circuit according to the first embodiment. In FIG. 14, storage devices 50, 52 and 56 such as magnetic disk drives, a frame image generation unit 54, an alignment unit 57, and a comparison unit 58 are arranged in the comparison circuit 108. Each of the “units” such as the frame image generation unit 54, the alignment unit 57 and the comparison unit 58 includes processing circuitry. The processing circuitry includes an electric circuit, a computer, a processor, a circuit board, a quantum circuit, a semiconductor device, or the like. Further, common processing circuitry (same processing circuitry), or different processing circuitry (separate processing circuitry) may be used for each of the “units”. Input data needed in the frame image generation unit 54, the alignment unit 57 and the comparison unit 58, or a calculated result is stored in a memory (not shown) or in the memory 118 each time.

Measured image data (stripe image) transmitted into the comparison circuit 108 is stored in the storage device 50. Reference image data transmitted into the comparison circuit 108 is stored in the storage device 52.

The frame image generation unit 54 generates the frame image 31 of each of a plurality of frame regions 30 by further dividing data of a stripe image acquired by scanning with each primary electron beam 10. The frame region 30 is used as a unit region of an inspection image to be inspected. In order to prevent missing an image, it is preferable that the margin region of each frame region 30 overlaps with each other. The generated frame image 31 is stored in the storage device 56.

Next, the alignment unit 57 reads the frame image 31 serving as an inspection image, and a reference image corresponding to the frame image 31 concerned, and provides alignment between both the images, based on units of sub-pixels smaller than units of pixels. For example, the alignment can be performed by a least squares method.

Then, the comparison unit 58 compares at least a portion of an acquired secondary electron image with a predetermined image. Here, a frame image obtained by further dividing an image of the sub-irradiation region 29 acquired with each beam is used. The comparison unit 58 compares, for each pixel, the frame image 31 and a reference image. The comparison unit 58 compares them, for each pixel, based on predetermined determination conditions so as to determine whether there is a defect such as a shape defect. For example, if a difference in gray scale level for each pixel is larger than a determination threshold Th, it is determined that there is a defect. Then, the comparison result is output. It may be output to the storage device 109 or the memory 118, or alternatively, output from the printer 119.

In the examples described above, the die-to-database inspection is performed. However, it is not limited thereto. A die-to-die inspection may be performed. In the case of the die-to-die inspection, alignment and comparison that have been described above are carried out between the frame image 31 (die 1) to be inspected and another frame image 31 (die 2) (another example of a reference image) in which there is formed the same pattern as that of the frame image 31 to be inspected.

The image acquisition mechanism 150 performs the scanning operation described above for each stripe region 32. In contrast, the contact point conductivity inspection circuit 138 performs a contact point conductivity inspection before starting a scanning operation by the image acquisition mechanism 150, or at a time, after starting the scanning operation, between scanning a predetermined stripe region and scanning the next stripe region. The time indicates a time during moving in a stripe region by the stage 105, or a time before starting scanning the next stripe region after scanning a predetermined stripe region and before or after the moving. Specifically, the inspection power supply 64 applies the inspection electric potential Vin, superimposed on a retarding potential, at a time between scanning one stripe region and scanning the next stripe region. The current detector 44 detects the current I at the time between scanning one stripe region and scanning the next stripe region in order to calculate a resistance as described above, and determines whether there is a contact point defect. If it is determined that there is a contact point defect, applying a retarding potential to the substrate 101 is stopped. Then, subsequent image-acquiring is stopped. By this, a useless scanning operation can be avoided. A re-inspection can be performed after resolving the contact point defect.

As described above, according to the first embodiment, a conductive state between the contact points A, B, and C and the substrate can be checked during applying a retarding potential. Therefore, it is possible to determine up to what point the image acquirement was in a normal state. Thus, re-inspection becomes unnecessary. Furthermore, since applying a retarding potential can be stopped before the conductive state between a contact point and a target object is severely impaired during applying the retarding potential, damage to the target object by an electric discharge, etc. can be avoided.

### Second Embodiment

Although the first embodiment describes the configuration where the inspection power supply 64 and the current detector 44 are non-contact electrically connected to a circuit which applies a retarding potential, it is not limited thereto. A second embodiment describes a configuration where an inspection power supply and a current detector are in contact connected to a circuit which applies a retarding potential. In the second embodiment, the configuration of the inspection apparatus 100 is the same as that of FIG. 1. Furthermore, in the following, the contents of the second embodiment are the same as those of the first embodiment except for what is particularly described below.

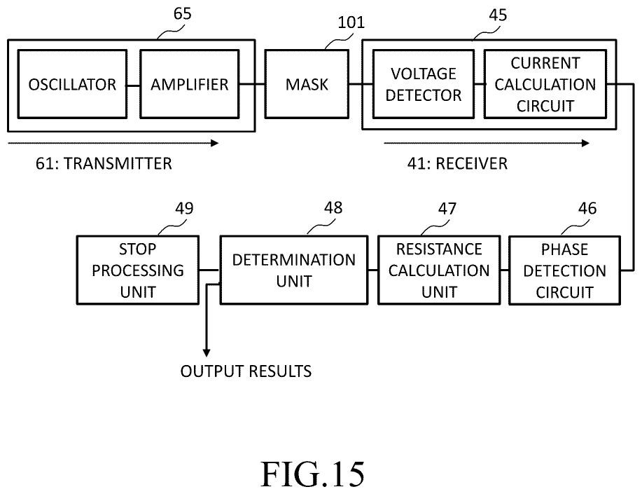

FIG. 15 is a block diagram showing an example of an internal configuration of a contact point conductivity inspection circuit according to the second embodiment.

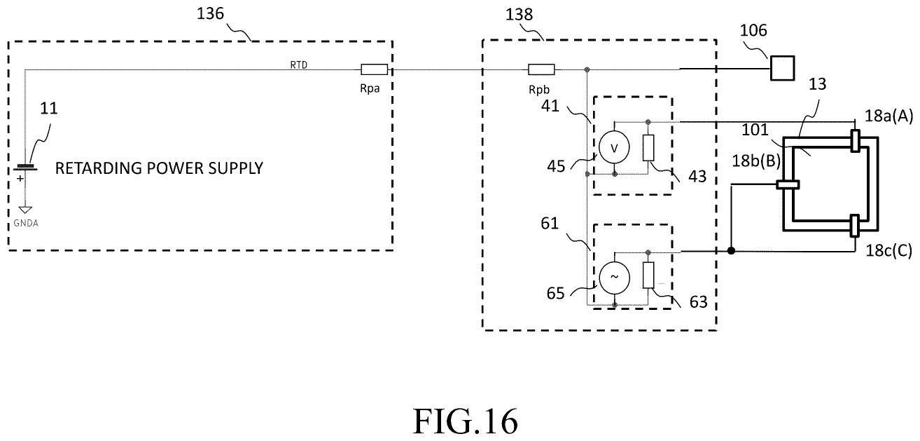

FIG. 16 is a circuit diagram for explaining a method of conductivity inspection according to the second embodiment.

In FIG. 15, in the contact point conductivity inspection circuit 138, there are arranged a transmitter 61, a receiver 41, a phase detection circuit 46, a resistance calculation unit 47, a determination unit 48, and a stop processing unit 49. In the transmitter 61, a resistance 63 and an inspection power supply 65 are connected in parallel. In the example of FIG. 15, the inspection power supply 65 includes an oscillator and an amplifier. Thereby, an alternating voltage can be generated. In the receiver 41, a resistance 43 and a current detector 45 are connected in parallel. The current detector 45 includes a voltage detector and a current calculation circuit. The current calculation circuit calculates a current value by dividing a voltage measured by the voltage detector by a resistance value of the resistance 43.

In FIG. 16, a resistance Rpa is disposed close to the outlet of the wiring of the retarding power supply circuit 136, and a resistance Rpb is disposed close to the inlet of the wiring of the contact point conductivity inspection circuit 138. In FIG. 16, the phase detection circuit 46, the resistance calculation unit 47, the determination unit 48, and the stop processing unit 49 are not illustrated in the contact point conductivity inspection circuit 138.

In the retarding power supply circuit 136, the retarding power supply 11 and the resistance Rpa are arranged. The negative electrode of the retarding power supply 11 used as a direct current power supply is connected to the contact point conductivity inspection circuit 138 through the resistance Rpa. The positive electrode of the retarding power supply 11 is connected to a ground (GND).

In the contact point conductivity inspection circuit 138, the wiring to which a negative retarding potential is applied branches through the resistance Rpb. For example, it branches to three lines. The wiring of the first system is connected in parallel, through the transmitter 61, to two contact points B and C (pins 18b and 18c) of the substrate cover 13, for example. The wiring of the second system is connected, through the receiver 41, to one contact point A (pin 18a) of the substrate cover 13, for example. The wiring of the third system is connected to the mark stand 106.

In FIG. 16, the inspection power supply 65 is in contact connected to a circuit which applies a retarding potential to at least one contact point (e.g., the contact point B or C) of a plurality of contact points A, B, and C. The following provides a detailed description.

The wiring of the first system branched close to the inlet of the contact point conductivity inspection circuit 138 is connected in parallel to one terminal of the resistance 63 of the transmitter 61, and one terminal of the inspection power supply 65. The other terminal of the resistance 63 and the other terminal of the inspection power supply 65 are connected in parallel to the two contact points B and C (pins 18b and 18c) of the substrate cover 13, for example.

In FIG. 16, the current detector 45 is in contact connected to a circuit which applies a retarding potential to at least one other contact point (e.g., the contact point A) of a plurality of contact points A, B, and C. The following provides a detailed description.

The wiring of the second system branched close to the inlet of the contact point conductivity inspection circuit 138 is connected in parallel to one terminal of the resistance 43 of the receiver 41 and one terminal of the current detector 45 (specifically, internal voltage detector). The other terminal of the resistance 43 and the other terminal of the current detector 45 (specifically, internal voltage detector) are connected in parallel to one contact point A (pin 18a) of the substrate cover 13, for example.

The retarding power supply circuit 136 applies a retarding potential to the substrate 101 through a plurality of contact points A, B, and C which are connected to the substrate 101 placed on the stage 105. Here, the retarding power supply circuit 136 applies a negative retarding potential to the plurality of contact points A, B, and C. Then, each of the plurality of contact points A, B, and C connected to the substrate 101 applies a retarding potential to the substrate 101. By this, the same retarding potential is applied to both the substrate 101 and the mark stand 106, and therefore, they become equipotential.

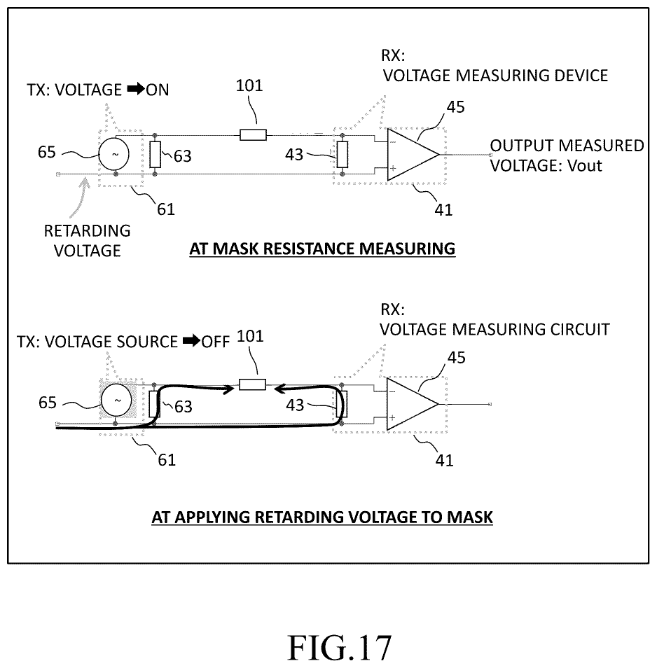

FIG. 17 is an illustration for explaining an example of applying an electric potential according to the second embodiment. When the inspection power supply 65 of the transmitter 61 is OFF, a retarding potential of the first line is applied to the contact points B and C through the resistance 63. The resistance in the case of the inspection power supply 65 being OFF is formed to be higher than the parallel resistance 63. As a result, a retarding potential is applied to the contact points B and C. In contrast, when the inspection power supply 65 of the transmitter 61 is ON, the inspection electric potential Vin from the parallel inspection power supply 65 can be applied, superimposed on the retarding potential, to the contact points B and C.

Then, in the state in which a retarding potential has been applied to a plurality of contact points A, B, and C (pins 18a, 18b, and 18c), the inspection power supply 65 applies an alternating current inspection electric potential Vin, superimposed on the retarding potential, to at least one contact point of the plurality of contact points A, B, and C. An alternating current potential is used for the inspection electric potential Vin. For example, the inspection electric potential Vin which has been oscillated at a frequency of 1 to 5 kHz (e.g., 2 kHz), for example, by an oscillator, and amplified to 1 to 5 V (e.g., 2 V), for example, is output. For example, the inspection electric potential Vin, which is a sufficiently small alternating current with respect to a retarding potential having a strong electric potential such as −15 kV, is output.

Then, in the state in which a retarding potential has been applied to a plurality of contact points A, B, and C (pins 18a, 18b, and 18c), and, further, the inspection electric potential Vin has been applied, to be superimposed on the retarding potential, to at least one contact point (e.g., the contact point B or C) of the plurality of contact points A, B, and C, the current detector 45 detects the current I flowing through at least one other contact point (e.g., the contact point A) which is different from the above-described at least one contact point (e.g., the contact point B or C) of a plurality of contact points A, B, and C.

The contents of operations, after detecting a current, of the phase detection circuit 46, the resistance calculation unit 47, the determination unit 48, and the stop processing unit 49 are the same as those of the first embodiment.

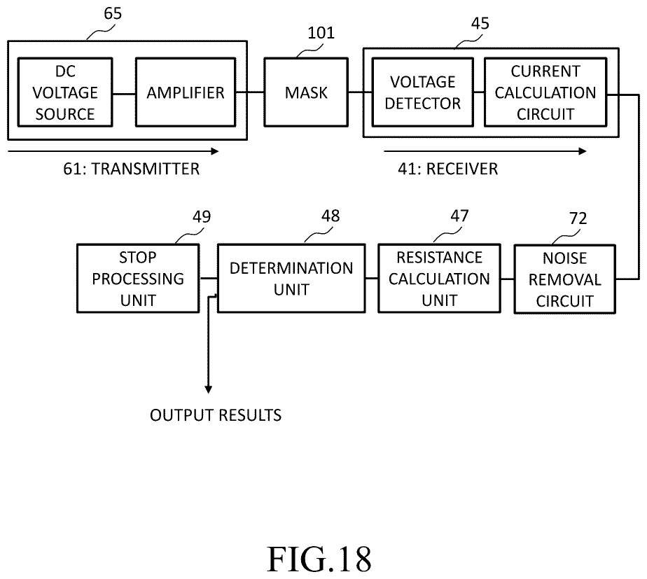

FIG. 18 is a block diagram showing another example of an internal configuration of a contact point conductivity inspection circuit according to the second embodiment. Although FIG. 15 describes the case of applying an alternating current potential as an inspection potential, it is not limited thereto. A direct current potential may be applied as the inspection electric potential. In the example of FIG. 18, a DC voltage source is arranged instead of the oscillator of the inspection power supply 65, and a noise removal circuit 72 is arranged instead of the phase detection circuit 46. The other points are the same as those of FIG. 15. In the inspection power supply 65, a direct current voltage generated by the DC voltage source is amplified by an amplifier to be output. Thereby, in the state in which a retarding potential has been applied to a plurality of contact points A, B, and C (pins 18a, 18b, and 18c), the inspection power supply 65 applies a direct current inspection electric potential Vin, superimposed on the retarding potential, to at least one contact point of the plurality of contact points A, B, and C.

As described referring to FIG. 17, when the inspection power supply 65 of the transmitter 61 is OFF, a retarding potential of the first line is applied to the contact points B and C through the resistance 63. The resistance in the case of the inspection power supply 65 being OFF is formed to be higher than the parallel resistance 63. As a result, a retarding potential is applied to the contact points B and C. In contrast, when the inspection power supply 65 of the transmitter 61 is ON, a direct current inspection electric potential Vin from the parallel inspection power supply 65 can be applied, superimposed on the retarding potential, to the contact points B and C.

Then, with respect to the receiver 41, in the state in which a retarding potential has been applied to a plurality of contact points A, B, and C (pins 18a, 18b, and 18c), and, further, the inspection electric potential Vin has been applied, to be superimposed on the retarding potential, to at least one contact point (e.g., the contact point B or C) of the plurality of contact points A, B, and C, the current detector 45 detects the current I flowing through at least one other contact point (e.g., the contact point A) of the plurality of contact points A, B, and C.

Next, the noise removal circuit 72 removes noise components of the detected current. Then, the resistance calculation unit 47 calculates a resistance R through at least one contact point (e.g., the contact point B or C), the substrate 101, and at least one other contact point (e.g., the contact point A) by dividing the direct current inspection electric potential Vin by an obtained current value. The contents of operations of the determination unit 48 and the stop processing unit 49 are the same as those of the first embodiment.

As described above, according to the second embodiment, even when connecting to a circuit, in contact, without using the transformers 62 and 42, a conductive state between the contact points A, B, and C and the substrate 101 can be, similarly, checked during applying a retarding potential.

In the above description, each “ . . . circuit” includes processing circuitry. The processing circuitry includes an electric circuit, a computer, a processor, a circuit board, a quantum circuit, a semiconductor device, or the like. Each “ . . . circuit” may use common processing circuitry (the same processing circuitry), or different processing circuitry (separate processing circuitry). Programs for causing a processor, etc. to execute processing may be stored in a recording medium, such as a magnetic disk drive, magnetic tape drive, FD, ROM (Read Only Memory) or the like. For example, the position circuit 107, the comparison circuit 108, the reference image generation circuit 112, and the like may be formed by at least one processing circuit described above.

Embodiments have been explained referring to specific examples described above. However, the present invention is not limited to these specific examples.

While the apparatus configuration, control method, and others not directly necessary for explaining the present invention are not described, some or all of them can be appropriately selected and used on a case-by-case basis when needed.

Any electron beam irradiation apparatus and contact point conductivity inspection method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron beam irradiation apparatus comprising:
a stage configured to mount thereon a target object;
an electron beam column configured to irradiate the target object with an electron beam;
a plurality of contact points connected to the target object and each configured to apply a retarding potential to the target object;
a retarding power supply configured to apply the retarding potential to the plurality of contact points;
an inspection power supply connected to at least one contact point of the plurality of contact points, and configured, in a state in which the retarding potential has been applied to the plurality of contact points, to apply an inspection electric potential to be superimposed on the retarding potential; and
a current detector connected to at least one other contact point which is different from the at least one contact point of the plurality of contact points, and configured, in a state in which the retarding potential has been applied to the plurality of contact points, and, further, the inspection electric potential has been applied, superimposed on the retarding potential, to the at least one contact point, to detect a current flowing through the at least one other contact point.

2. The apparatus according to claim 1, wherein
the inspection power supply is non-contact electrically connected to a circuit which applies the retarding potential to the at least one contact point, and
the current detector is non-contact electrically connected to a circuit which applies the retarding potential to the at least one other contact point.

3. The apparatus according to claim 1, wherein
the inspection power supply is in contact connected to a circuit which applies the retarding potential to the at least one contact point, and
the current detector is in contact connected to a circuit which applies the retarding potential to the at least one other contact point.

4. The apparatus according to claim 1, wherein the inspection electric potential is an alternating current potential.

5. The apparatus according to claim 1, further comprising:
a first transformer configured to non-contact electrically connect the inspection power supply and a circuit which applies the retarding potential to the at least one contact point; and
a second transformer configured to non-contact electrically connect the current detector and a circuit which applies the retarding potential to the at least one other contact point.

6. The apparatus according to claim 5, wherein
the inspection power supply is connected to a primary side coil of the first transformer, and
the circuit which applies the retarding potential to the at least one contact point is connected to a secondary side coil of the first transformer.

7. The apparatus according to claim 5, wherein
the circuit which applies the retarding potential to the at least one other contact point is connected to a primary side coil of the second transformer, and
the current detector is connected to a secondary side coil of the second transformer.

8. A contact point conductivity inspection method comprising:
applying a retarding potential to a target object placed on a stage via each of a plurality of contact points connected to the target object;
applying, in a state in which the retarding potential has been applied to the plurality of contact points, an inspection electric potential, to be superimposed on the retarding potential, to at least one contact point of the plurality of contact points;
detecting, in a state in which the retarding potential has been applied to the plurality of contact points, and, further, the inspection electric potential has been applied, superimposed on the retarding potential, to the at least one contact point, a current flowing through at least one other contact point which is different from the at least one contact point of the plurality of contact points;
calculating, using a detected current value, a resistance, which is through the target object, between the at least one contact point and the at least one other contact point; and
determining, using the resistance, whether a contact between the target object and either one of the at least one contact point and the at least one other contact point of the plurality of contact points has been damaged, and outputting a result of the determining.

9. The method according to claim 8, wherein
a surface region of the target object is divided into a plurality of stripe regions, further comprising:
performing scanning, for each of the plurality of stripe regions, in the state in which the retarding potential has been applied to the plurality of contact points, with an electron beam while moving the stage, wherein
the inspection electric potential is applied, at a time between scanning one stripe region and scanning a next stripe region, to detect the current.

10. The method according to claim 8, wherein,
as a result of the determining, in a case it is determined that a contact between the target object and either one of the at least one contact point and the at least one other contact point of the plurality of contact points has been damaged, the applying the retarding potential is stopped.
